(19) United States
(12) Patent Application Publication
(10) Pub. No.: US 2012/0171512 A1
(43) Pub. Date: Jul. 5, 2012

(54) PROCESS FOR SURFACE TREATING MAGNESIUM ALLOY AND ELECTROMAGNETIC SHIELDING ARTICLE MADE WITH SAME

(75) Inventors: CHWAN-HWA CHIANG, Shindian (TW); ZHI-QIANG LI, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/211,734

(22) Filed: Aug. 17, 2011

(30) Foreign Application Priority Data
Dec. 29, 2010 (CN) 201010612227.3

(51) Int. Cl. B32B 15/08; C23C 14/34

(52) U.S. Cl. 428/626; 204/192.15

(57) ABSTRACT

A process for treating the surface of magnesium alloy comprises providing a substrate made of magnesium alloy. A chromium layer is then formed on the substrate by magnetron sputtering and a titanium layer is formed on the substrate by magnetron sputtering. A protective layer is formed on the titanium layer. The protective layer is an epoxy resin coating.

### BACKGROUND

1. Technical Field

The disclosure generally relates to a process for surface treating magnesium alloy, and electromagnetic shielding articles made with magnesium alloy treated by the process.

2. Description of Related Art

Magnesium alloys are widely used in manufacturing components of electronic devices such as mobile phones, televisions, radios, and computers because of their lightweight property and quick heat dissipation. However, most components made with magnesium alloy do not undergo any electromagnetic shielding treatment, thus cannot meet an increasingly strict electromagnetic shielding requirements. Furthermore, magnesium alloys have a relatively low erosion resistance and abrasion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for the surface treating of magnesium alloy and electromagnetic shielding article made with magnesium alloy treated by the process. Moreover, in the drawings, like reference numerals designate corresponding parts throughout the several views. Wherever possible, the same reference numbers are used throughout the drawings to refer to the same or like elements of an embodiment.

FIG. 1 is a cross-sectional view of an exemplary article created by the present process.

FIG. 2 is a schematic view of a vacuum sputtering machine for processing the exemplary article shown in FIG. 1.

### DETAILED DESCRIPTION

An exemplary process for the surface treatment of magnesium alloy may include the following steps.

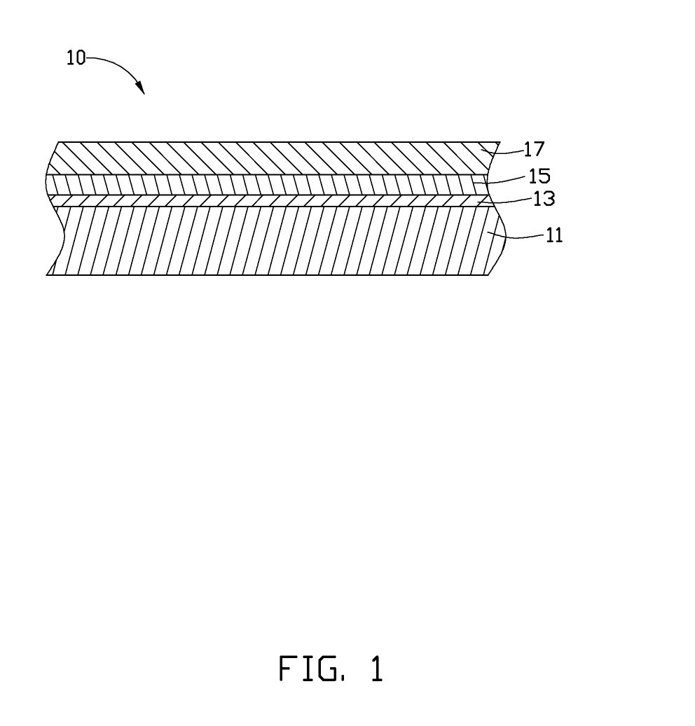

Referring to FIG. 1, a substrate 11 is provided. The substrate 11 is made of a magnesium alloy, such as Mg—Al alloy, or Mg—Al—Zn alloy. The substrate 11 can be made by punching.

The substrate 11 is pretreated. For example, the substrate 11 is cleaned with a solution (e.g., alcohol or acetone) in an ultrasonic cleaner for about 10 min to 30 min, to remove impurities such as grease or dirt from the substrate 11. Then, the substrate 11 is dried.

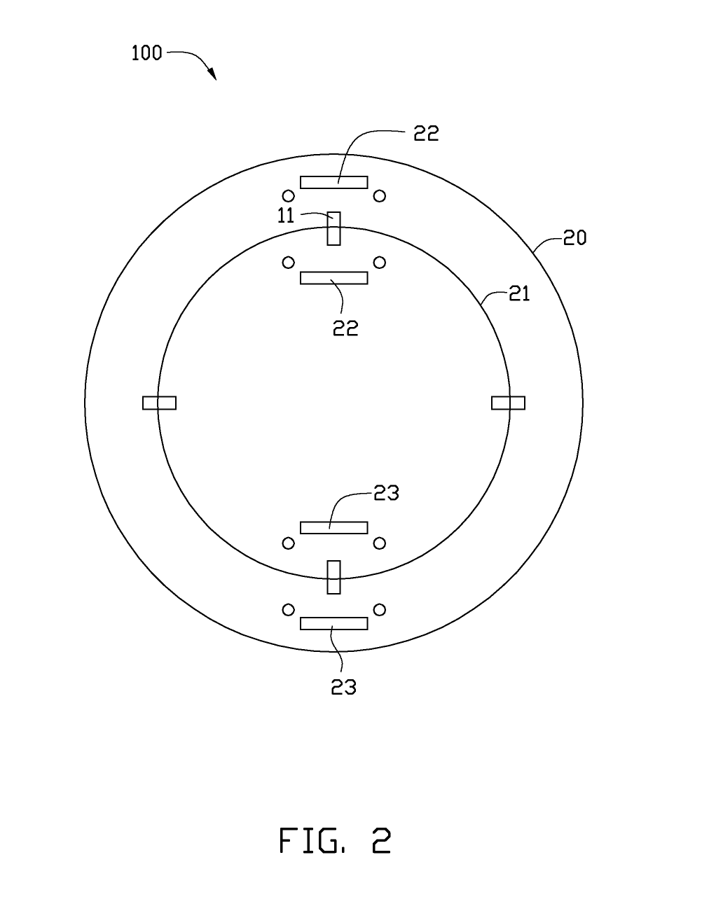

The substrate 11 is plasma cleaned. The substrate 11 is held on a rotating bracket 21 in a vacuum chamber 20 of a vacuum sputtering machine 100 as shown in FIG. 2. In this exemplary embodiment, the vacuum sputtering machine 100 is a magnetron sputtering machine. The vacuum chamber 20 is fixed with chromium targets 22 and titanium targets 23 therein. The vacuum chamber is evacuated to about 1.0×10⁻³ Pa-3.0×10⁻³ Pa. Argon (Ar, having a purity of about 99.999%) is fed into the chamber at a flow rate of about 100 standard-state cubic centimeters per minute (sccm) to 300 sccm. A bias voltage of about −150 V to about −300 V is applied to the substrate 11. Ar is ionized to plasma. The plasma then strikes the surface of the substrate 11 to clean the surface of the substrate 11. Plasma cleaning the substrate 11 may take about 5 minutes (min) to 10 min. The plasma cleaning process further removes any impurities on the substrate 11. Thus, the bond between the substrate 11 and the subsequently formed coating will be enhanced.

When the plasma cleaning is finished, a chromium layer 13 is formed on the substrate 11 by magnetron sputtering. This step may be carried out in the vacuum sputtering machine 100. The chamber 20 maintains an internal pressure of about 1.0×10⁻³ Pa-3.0×10⁻³ Pa and the inside of the chamber 20 is heated to a temperature of about 150° C.-200° C. The flow rate of the Ar is adjusted to be about 100 sccm-300 sccm. A bias voltage of about −150 V to about −200 V is applied to the substrate 11. About 20 kW to about 40 kW of power is applied to the chromium targets 22 fixed in the chamber 20, depositing the chromium layer 13 on the substrate 11. Depositing the chromium layer 13 may take about 10 min-15 min. The thickness of the chromium layer 13 may be about 100 nm-500 nm.

A titanium layer 15 is then directly formed on the chromium layer 13 by magnetron sputtering. This step may be carried out in the same vacuum sputtering machine 100. The chromium targets 22 are switched off. The chamber 20 maintains an internal pressure of about 1.0×10⁻³ Pa-3.0×10⁻³ Pa, and the inside of the chamber 20 maintains a temperature of about 150° C.-200° C. The flow rate of argon maintains at about 100 sccm-300 sccm. A bias voltage of about −150 V to about −200 V is applied to the substrate 11. About 20 kW to about 40 kW of power is applied to the titanium targets 23 fixed in the chamber 20, depositing a titanium layer 15 on the chromium layer 13. Depositing the titanium layer 15 may take about 45 min-60 min. The thickness of the titanium layer 15 may be about 100 nm-1000 nm.

A protective coating 17 is directly formed on the titanium layer 15. The protective coating 17 may be an epoxy resin coating. The protective coating 17 can be formed by spraying. The thickness of the protective coating 17 may be about 50 μm-80 μm.

The chromium layer 13 has a high bonding force with the substrate 11, thus strengthens the bonding of the substrate 11 and the titanium layer 15. The chromium layer 13 and the titanium layer 15 both have good electrical conductivity and have a low resistance, so the chromium layer 13 and the titanium layer 15 can provide effective electromagnetic shielding. The protective layer 17 provides a good erosion resistance for the substrate 11 and protects the chromium layer 13 and the titanium layer 15 from being damaged and losing shielding functionality.

FIG. 1 shows a cross-section of an exemplary article 10 made of magnesium alloy and processed by the surface treatment process described above. The article 10 may be an electromagnetic shield inside an electronic device, such as a mobile phone. The article 10 includes the substrate 11 made of magnesium alloy having the chromium layer 13, the titanium layer 15 13, and the protective coating 17 formed thereon and in that order. The thickness of the chromium layer 13 may be about 100 nm-500 nm. The thickness of the titanium layer 15 may be about 100 nm-1000 nm. The thickness of the protective coating 17 may be about 50 μm-80 μm. The chromium layer 13 and the titanium layer 15 have a total resistance of no more than 0.5 ohms. The article 10 has a shielding effectiveness of about 60 decibel (dB) to about 70 dB.

### EXAMPLES

Experimental examples of the present disclosure are described as follows. An “AS600DMTX05-X” type vacuum sputtering machine made by ProChina Ltd., is used in the following examples.

### Example 1

A sample of AZ91D type magnesium alloy substrate is cleaned with alcohol in an ultrasonic cleaner for about 25 minutes and then is placed into the vacuum chamber 20 of the vacuum sputtering machine 100. The vacuum chamber 20 is evacuated to maintain an internal pressure of about 1.5×10⁻³ Pa. Ar is fed into the vacuum chamber 20 at a flow rate of about 150 sccm. A bias voltage of about −200 V is applied to the substrate, plasma cleaning the substrate 11 for about 5 min.

The inside of the vacuum chamber 20 is heated to a temperature of about 150° C. The flow rate of the Ar is about 150 sccm. A bias voltage of about −200 V is applied to the substrate. About 30 kW of power is applied to the chromium targets 22 for about 10 min, depositing a chromium layer on the substrate.

The chromium targets 22 are switched off. About 30 kW of power is applied to the titanium targets 23 for about 50 min, depositing a titanium layer on the chromium layer. Other parameters are same as during deposition of the chromium layer.

Then a protective coating is formed on the titanium layer. A liquid coating material is sprayed on the titanium layer by a spraying gun with a spray nozzle having a diameter of about 2 mm at a spraying pressure of about 2.0×10⁻⁵ Pa, and cured via UV irradiation, forming a protective coating. The liquid coating material mainly comprises of 85% epoxy resin by weight and xylene as solvent. The thickness of the protective coating is about 50 μm-80 μm.

### Example 2

A sample of AM60B magnesium alloy substrate is cleaned with alcohol in an ultrasonic cleaner for about 25 minutes and then is placed into the vacuum chamber 20 of the vacuum sputtering machine 100. The vacuum chamber 20 is evacuated to maintain an internal pressure of about 2.0×10⁻³ Pa. Ar is fed into the vacuum chamber 20 at a flow rate of about 200 sccm. A bias voltage of about −150 V is applied to the substrate, plasma cleaning the substrate 11 for about 5 min.

The inside of the vacuum chamber 20 is heated to a temperature of about 200° C. The flow rate of the Ar is about 200 sccm. The bias voltage applied to the substrate is about −150 V. About 30 kW of power is applied to the chromium targets 22 for about 15 min, depositing a chromium layer on the substrate.

The chromium targets 22 are switched off. About 30 kW of power is applied to the titanium targets 23 for about 60 min, depositing a titanium layer on the chromium layer. Other parameters are same as during deposition of the chromium layer.

Then a protective coating is formed on the titanium layer. A liquid coating material is sprayed on the titanium layer by a spraying gun with a spray nozzle having a diameter of about 2 mm at a spraying pressure of about 2.0×10⁻⁵ Pa, and cured via UV irradiation, forming a protective coating. The liquid coating material mainly comprises of 85% epoxy resin by weight and xylene as solvent. The thickness of the protective coating is about 50 μm-80 μm.

### Results of the Above Examples

The surface resistance of the samples created by above examples was tested by a film resistance meter. Result shows that the samples created by example 1 and 2 have a surface resistance of about 0.3 ohms and 0.5 ohms, respectively.

The electromagnetic shielding effectiveness of the samples created by above examples was tested by an “E5073” type electromagnetic shielding test apparatus sold by Agilent Company. During the frequency of about 0.5 GHz-3 GHz, the sample created by example 1 and the sample created by example 2 have a shielding effectiveness of about 68 dB and about 62 dB, respectively. The result shows that the samples created by the present process have good shielding effectiveness.

Furthermore, a neutral salt spray test was applied to the samples created by example 1 and 2. The test conditions included 5% NaCl (similar to salt-fog chloride levels), and the test was an accelerated corrosion test for assessing coating performance. Erosion was observed after about 72 hours, indicating that the samples yielding from the present process have a good erosion resistance.

Additionally, the samples created by example 1 and 2 were subjected to the cross-hatch adhesion test according to the ASTM-D3359 “Standard Test Methods for Measuring Adhesion by Tape Test”. Each of the samples achieves a test value of 5 B, showing that no flaking had occurred.

Finally, the samples created by example 1 and 2 were also subjected to the wet thermal shock test between 25° C. and 55° C. for 2 cycles with 25° C. point maintained for about 3 hours and 55° C. point maintained for about 9 hours. The test was carried out under a relative humidity of 95% RH. No peeling was observed with the samples.

It is to be understood, however, that even through numerous characteristics and advantages of the exemplary disclosure have been set forth in the foregoing description, together with details of the system and functions of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A process for surface treating magnesium alloy, the process comprising the following steps of:
providing a substrate made of magnesium alloy;
forming a chromium layer on the substrate by magnetron sputtering;
forming a titanium layer on the chromium layer by magnetron sputtering; and
forming a protective coating on the titanium layer, the protective coating being an epoxy resin coating.

2. The process as claimed in claim 1, wherein during magnetron sputtering of the chromium layer, about 20 kW-40 kW of power is applied to chromium targets; argon at a flow rate of about 100 sccm to about 300 sccm is used as a sputtering gas; a bias voltage of about −150 V to about −200 V is applied to the substrate; and the sputtering temperature is about 150° C. to about 200° C.

3. The process as claimed in claim 2, wherein magnetron sputtering of the chromium layer takes about 10 min-15 min.

4. The process as claimed in claim 1, wherein during magnetron sputtering of the titanium layer, about 20 kW-40 kW of power is applied to titanium targets; argon at a flow rate of about 100 sccm to about 300 sccm is used as a sputtering gas; a bias voltage of about −150 V to about −200 V is applied to the substrate; and the sputtering temperature is about 150° C. to about 200° C.

5. The process as claimed in claim 4, wherein magnetron sputtering of the titanium layer takes about 45 min-60 min.

6. The process as claimed in claim 1, wherein the protective coating is formed by spraying.

7. The process as claimed in claim 6, wherein during forming of the protective coating, a liquid coating material was sprayed on the titanium layer by a spraying gun with a spray nozzle having a diameter of about 2 mm at a spraying pressure of about 2.0×10⁻⁵ Pa, and then cured.

8. The process as claimed in claim 7, wherein the liquid coating material mainly comprises of 85% epoxy resin by weight and xylene as solvent.

9. The process as claimed in claim 1, further comprising a step of plasma cleaning the substrate, before forming the chromium layer.

10. An article, comprising:
a substrate made of magnesium alloy;
a chromium layer formed on the substrate;
a titanium layer formed on the chromium layer; and
a protective coating formed on the titanium layer, the protective coating being an epoxy resin coating.

11. The article as claimed in claim 10, wherein the thickness of the chromium layer is about 100 nm-500 nm.

12. The article as claimed in claim 10, wherein the thickness of the titanium is about 100 nm-1000 nm.

13. The article as claimed in claim 10, wherein the thickness of the protective coating was about 50 μm-80 μm.
